(19) United States
(12) Patent Application Publication
(10) Pub. No.: US 2026/0114154 A1
(43) Pub. Date: Apr. 23, 2026

(54) DISPLAY APPARATUS, DISPLAY PANEL, AND METHOD OF MANUFACTURING DISPLAY PANEL

(71) Applicant: HKC CORPORATION LIMITED, SHENZHEN (CN)

(72) Inventors: Yangling TANG, SHENZHEN (CN); Zhisheng XIE, SHENZHEN (CN); Qin LIANG, SHENZHEN (CN); Haijiang YUAN, SHENZHEN (CN)

(73) Assignee: HKC CORPORATION LIMITED, SHENZHEN (CN)

(21) Appl. No.: 19/252,969

(22) Filed: Jun. 27, 2025

(30) Foreign Application Priority Data
Jul. 15, 2024 (CN) 202410950787.1

(51) Int. Cl. H10K 59/80; H10K 59/12; H10K 59/122; H10K 59/131

(52) U.S. Cl. CPC H10K 59/873; H10K 59/1201; H10K 59/122; H10K 59/131

(57) ABSTRACT

The present application provides a display apparatus, a display panel, and a method of manufacturing a display panel. The display panel, having a display region and a border region located around the display region, includes: a driving structure layer, a pixel defining layer, and an encapsulation structure layer sequentially stacked; a dam structure, arranged in the border region and between the pixel defining layer and the encapsulation structure layer. The dam structure includes a first barrier structure, which includes a first barrier portion and a second barrier portion sequentially stacked in a direction from the driving structure layer to the encapsulation structure layer. A portion of the second barrier portion close to the display region extends beyond a top surface of the first barrier portion. A portion of the second barrier portion away from the display region does not extend beyond the top surface of the first barrier portion.

### CROSS-REFERENCE TO RELATED APPLICATIONS

The present application claims priority to Chinese Patent Application No. 202410950787.1, entitled “DISPLAY APPARATUS, DISPLAY PANEL, AND METHOD OF MANUFACTURING DISPLAY PANEL”, filed on Jul. 15, 2024, which is herein incorporated by reference in its entirety.

### TECHNICAL FIELD

The present disclosure relates to the technical field of displays, in particular, to a display apparatus, a display panel, and a method of manufacturing a display panel.

### BACKGROUND

A light-emitting device, such as organic light-emitting diode (OLED), is being increasingly widely applied to products such as televisions, mobile phones or the like due to its characteristics such as lightweight, energy-saving, wide color gamut, high contrast ratio, etc. In a process of manufacturing the OLED, an isolation structure between pixels is manufactured using a process route of overhang structure without using a mask, so as to improve the display effect of the pixels. When a thin-film encapsulation barrier structure is manufactured by the process route of overhang structure without using the mask, defects such as cracks, voids or the like easily occur in a lower side region of an eave structure within the overhang structure, thereby affecting subsequent processes.

### SUMMARY

A first technical solution adopted by the present disclosure is to provide a display panel, having a display region and a border region located around the display region, wherein the display panel includes:
a driving structure layer, a pixel defining layer, and an encapsulation structure layer sequentially stacked;
a dam structure, arranged in the border region and arranged between the pixel defining layer and the encapsulation structure layer;
wherein the dam structure includes a first barrier structure, the first barrier structure includes a first barrier portion and a second barrier portion sequentially stacked in a direction from the pixel defining layer to the encapsulation structure layer, a portion of the second barrier portion close to the display region extends beyond a top surface of the first barrier portion, and a portion of the second barrier portion away from the display region does not extend beyond the top surface of the first barrier portion.

A second technical solution adopted by the present disclosure is to provide a method of manufacturing a display panel, including:
obtaining a panel to be processed, the panel to be processed comprising a driving structure layer, a pixel defining layer, a first functional layer, and a second functional layer stacked sequentially, and the panel to be processed comprising a display region and a border region located around the display region;
sequentially removing a portion of the second functional layer and a portion of the first functional layer located in the border region to form a first window, a portion of the pixel defining layer being exposed through the first window, and an end portion of an inner sidewall of the first window formed by the second functional layer not extending beyond an end portion of an inner sidewall of the same first window formed by the first functional layer;
sequentially removing a portion of the second functional layer and a portion of the first functional layer on a side of the first window close to the display region to form a second window, enabling the first functional layer and the second functional layer in the border region to form at least the first barrier structure, the portion of the pixel defining layer being exposed through the second window, and an end portion of an inner sidewall of the second window formed by the second functional layer extending beyond an end portion of an inner sidewall of the same second window formed by the first functional layer;
forming an encapsulation structure layer on a side of the pixel defining layer where the first barrier structure is arranged.

A third technical solution adopted by the present disclosure is to provide a display apparatus, including a power supply and the display panel in the first technical solution.

### BRIEF DESCRIPTION OF THE DRAWINGS

To more clearly illustrate the technical solutions in the embodiments of the present disclosure, a brief introduction to the drawings used in some embodiments of the present disclosure is provided below. It is evident that the drawings described below are only some of the embodiments of the present disclosure. For those skilled in the art, additional drawings may be derived from these drawings without creative work.

FIG. 1 is a schematic planar structural view of a display panel provided by a technical solution in the related art.

FIG. 2 is a schematic cross-sectional view in an A-A orientation of the display panel provided in the embodiment of FIG. 1.

FIG. 3(a) is a schematic cross-sectional view after a barrier structure is covered by a first inorganic encapsulation layer in the related art.

FIG. 3(b) is a schematic cross-sectional view after a barrier structure is covered by a second inorganic encapsulation layer in the related art.

FIG. 4 is a schematic cross-sectional view of a display panel provided in a first embodiment of the present disclosure.

FIG. 5 is a schematic cross-sectional view of a dam structure provided in a second embodiment of the present disclosure.

FIG. 6 is a schematic cross-sectional view of a dam structure provided in a third embodiment of the present disclosure.

FIG. 7 is a schematic cross-sectional view of a dam structure provided in a fourth embodiment of the present disclosure.

FIG. 8 is a schematic cross-sectional view of a dam structure provided in a fifth embodiment of the present disclosure.

FIG. 9 is a schematic cross-sectional view of a dam structure provided in a sixth embodiment of the present disclosure.

FIG. 10 is a schematic planar structural view of the display panel provided in the embodiment of FIG. 4.

FIG. 11 is a schematic planar structural view of a display panel provided in some embodiments of the present disclosure.

FIG. 12 is a schematic planar structural view of a display panel provided in some embodiments of the present disclosure.

FIG. 13 is a schematic planar structural view of a display panel provided in some embodiments of the present disclosure.

FIG. 14 is a schematic flowchart of a method of manufacturing of a display panel provided in the present disclosure.

FIG. 15(a) is a schematic cross-sectional view of a dam structure corresponding to an operation in the manufacturing method of the display panel shown in FIG. 14.

FIG. 15(b) is a schematic cross-sectional view of a dam structure corresponding to an operation in the manufacturing method of the display panel shown in FIG. 14.

FIG. 15(c) is a schematic cross-sectional view of a dam structure corresponding to an operation in the manufacturing method of the display panel shown in FIG. 14.

FIG. 15(d) is a schematic cross-sectional view of a dam structure corresponding to an operation in the manufacturing method of the display panel shown in FIG. 14.

FIG. 15(e) is a schematic cross-sectional view of a dam structure corresponding to an operation in the manufacturing method of the display panel shown in FIG. 14.

FIG. 15(f) is a schematic cross-sectional view of a dam structure corresponding to an operation in the manufacturing method of the display panel shown in FIG. 14.

FIG. 15(g) is a schematic cross-sectional view of a dam structure corresponding to an operation in the manufacturing method of the display panel shown in FIG. 14.

FIG. 16 is a schematic structural view of a display apparatus provided in an embodiment of the present disclosure.

### DETAILED DESCRIPTION

The following provides a detailed description of the embodiments of the present disclosure in conjunction with the drawings of the specification.

In the following description, specific details such as particular system structures, interfaces, technologies or the like are provided for the purpose of illustration rather than limitation, so as to facilitate a thorough understanding of the present disclosure.

The technical solutions in the embodiments of the present disclosure will be described clearly and completely in the following in conjunction with the accompanying drawings in the embodiments of the present disclosure. It is evident that the embodiments described below are only some of the embodiments of the present disclosure and not all of them. All other embodiments obtained by those skilled in the art without creative effort shall fall within the scope of protection of the present disclosure.

The terms “first,” “second,” and “third” in the present disclosure are merely used for descriptive purposes and should not be construed as indicating or implying relative importance or implicitly indicating the number of the technical features indicated. Thus, features defined with “first,” “second,” and “third” may explicitly or implicitly include at least one such feature. In the description of the present disclosure, the term “multiple” means at least two, for example, two or three, unless specifically defined otherwise. All directional indications (such as up, down, left, right, front, back, etc.) in the embodiments of the present disclosure are only used to describe the relative positional relationship and movement status of components under a specific posture (as shown in the drawings). If the specific posture changes, the directional indications should also be adjusted accordingly. Furthermore, the terms “include,” “have,” and any variations thereof are intended to cover non-exclusive inclusion. For example, a process, a method, a system, a product, or an apparatus that includes a series of steps or components is not limited to those explicitly listed steps or components but may optionally include other steps or components not listed, or may optionally include inherent other steps or components.

References to “an embodiment” in the present disclosure mean that a particular feature, structure, or characteristic described in connection with the embodiment is included in at least one embodiment of the present disclosure. The phrase appearing in various places throughout the specification does not necessarily refer to the same embodiment, and embodiments are not mutually exclusive or alternative unless otherwise indicated. It is explicitly and implicitly understood by those skilled in the art that the embodiments described herein may be combined with other embodiments.

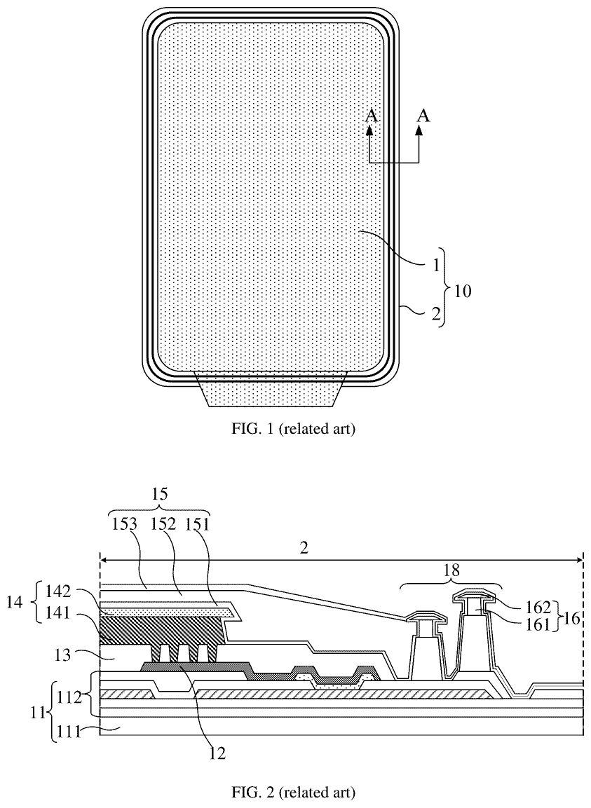

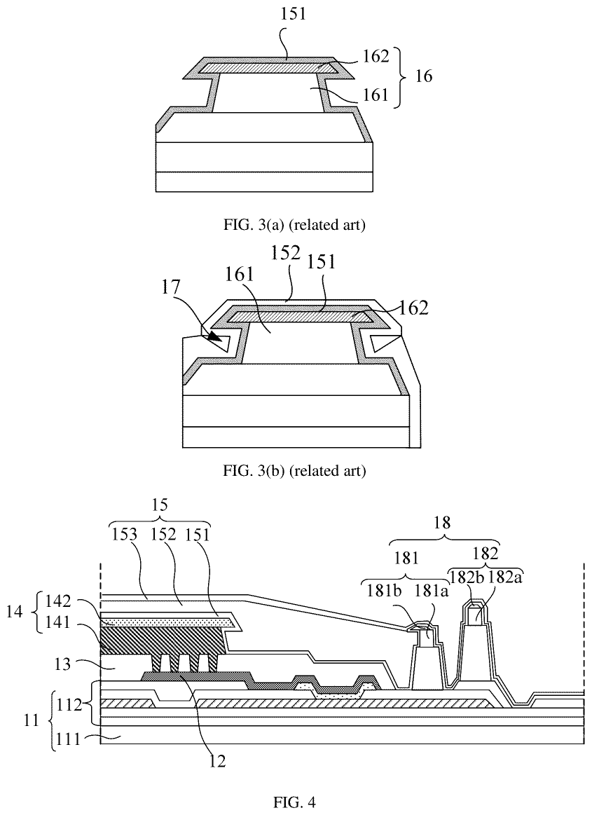

As shown in FIG. 1 to FIG. 3(b), FIG. 1 is a schematic planar structural view of a display panel provided by a technical solution in the related art, FIG. 2 is a schematic cross-sectional view in an A-A orientation of the display panel provided in the embodiment of FIG. 1, FIG. 3(a) is a schematic cross-sectional view after a barrier structure is covered by a first inorganic encapsulation layer in the related art, and FIG. 3(b) is a schematic cross-sectional view after a barrier structure is covered by a second inorganic encapsulation layer in the related art.

At present, when manufacturing a thin film encapsulation directly through a process route using a maskless overhang structure, defects such as a crack, a void 17 or the like easily occur in a lower side region of an eave structure within the overhang structure. In some embodiments, in a direction perpendicular to a display panel 10, the display panel 10 includes a driving structure layer 11, a pixel defining layer 13, and an encapsulation structure layer 15 sequentially stacked. The display panel 10 further includes a dam structure 18. The dam structure 18 is arranged in the border region 2 and is arranged between the driving structure layer 11 and the encapsulation structure layer 15. The dam structure 18 includes multiple barrier structures 16. Each barrier structure 16 includes a main body structure 161 and a top surface structure 162 that are stacked in a direction from the driving structure layer 11 toward the encapsulation structure layer 15. An edge of the top surface structure 162 extends beyond a top surface of the main body structure 161. The encapsulation structure layer 15 includes a first inorganic encapsulation layer 151, an organic encapsulation layer 152, and a second inorganic encapsulation layer 153 sequentially stacked in a direction away from the driving structure layer 11. The organic encapsulation layer 152 is an ink jet print (IJP) layer. The barrier structure 16 is configured to block a leveling of the organic encapsulation layer 152. The first inorganic encapsulation layer 151 and the second inorganic encapsulation layer 153 are stacked on an exposed driving structure layer 11 and an outer wall surface of the barrier structure 16. Since an edge of the top surface structure 162 in the barrier structure 16 extends beyond a top surface of the main body structure 161 to form an eave structure, a second inorganic encapsulation layer 153 at an end portion of the extended top surface structure 162 is likely to connect with a second inorganic encapsulation layer 153 on the driving structure layer 11, thereby forming a void 17 among an outer side surface of the main body structure 161, a lower surface of an extended top surface structure 162, and an upper surface of the driving structure layer 11. When the display panel 10 is heated, due to the thermal expansion and contraction of the air inside the void 17, cracks are likely to occur in the second inorganic encapsulation layer 153, thereby affecting the encapsulation performance of the encapsulation structure layer 15.

Furthermore, when it is necessary to form other wiring layers on the encapsulation structure layer 15 of the display panel 10, due to the structural instability of the encapsulation structure layer 15, there is a risk that other wiring layers laid on the encapsulation structure layer 15 may become disconnected.

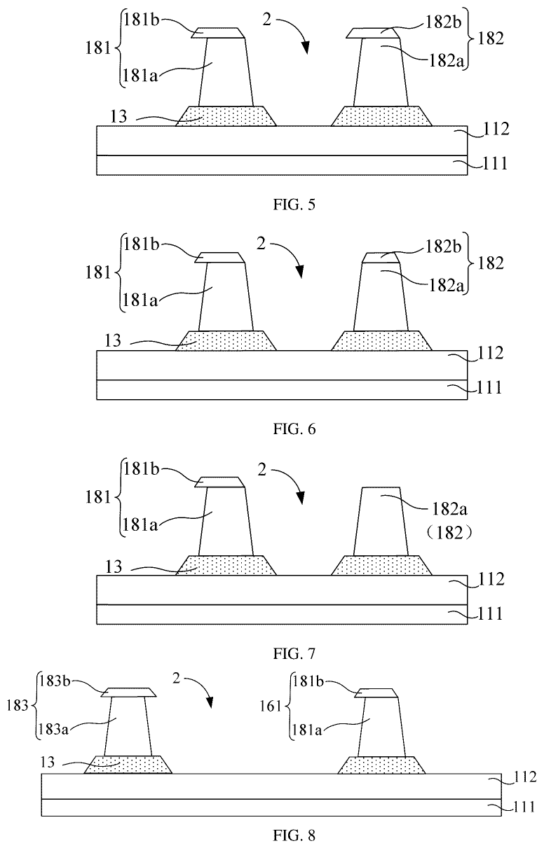

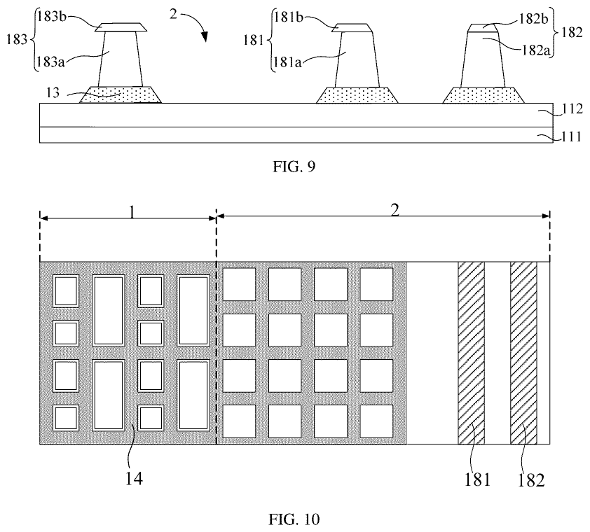

As shown in FIG. 4 to FIG. 10, FIG. 4 is a schematic cross-sectional view of a display panel provided in a first embodiment of the present disclosure, FIG. 5 is a schematic cross-sectional view of a dam structure provided in a second embodiment of the present disclosure, FIG. 6 is a schematic cross-sectional view of a dam structure provided in a third embodiment of the present disclosure, FIG. 7 is a schematic cross-sectional view of a dam structure provided in a fourth embodiment of the present disclosure, FIG. 8 is a schematic cross-sectional view of a dam structure provided in a fifth embodiment of the present disclosure, FIG. 9 is a schematic cross-sectional view of a dam structure provided in a sixth embodiment of the present disclosure, and FIG. 10 is a schematic planar structural view of the display panel provided in the embodiment of FIG. 4.

Based on the above problem, as shown in FIG. 4, the present disclosure provides a display panel 10. The display panel 10 has a display region 1 and a border region 2 located around the display region 1. The display panel 10 includes a driving structure layer 11, a pixel defining layer 13, and an encapsulation structure layer 15 sequentially stacked. The display panel 10 further includes a dam structure 18. The dam structure is arranged in the border region 2 and is arranged between the driving structure layer 11 and the encapsulation structure layer 15. The dam structure 18 includes a first barrier structure 181. The first barrier structure 181 includes a first barrier portion 181a and a second barrier portion 181b sequentially stacked in a direction from the driving structure layer 11 toward the encapsulation structure layer 15. A portion of the second barrier portion 181b close to the display region 1 extends beyond a top surface of the first barrier portion 181a. A portion of the second barrier portion 181b away from the display region 1 does not extend beyond the top surface of the first barrier portion 181a.

The first barrier structure 181 of the dam structure 18 provided in the present disclosure, by configuring an outer side surface of the second barrier portion 181b away from the display region 1 not to extend beyond a top surface of the first barrier portion 181a, a sidewall surface of the first barrier structure 181 away from the display region 1 does not form an eave structure, thereby avoiding defects such as cracks and voids 17 in the first barrier structure 181 caused by the eave structure. By extending the portion of the second barrier portion 181b close to the display region 1 beyond the top surface of the first barrier portion 181a, a sidewall surface of the first barrier structure 181 close to the display region 1 forms an eave structure, so as to facilitate an edge sealing of the encapsulation structure layer 15 and improve the encapsulation effect of the display panel 10.

The display panel 10 further includes a connection electrode 12 and a conductive isolation structure 14. The driving structure layer 11 includes a substrate 111 and a driving substrate 112 sequentially stacked. The pixel defining layer 13 is arranged on a side of the driving substrate 112 away from the substrate 111. The connection electrode 12 is arranged between the pixel defining layer 13 and the driving substrate 112, and the connection electrodes 12 are spaced apart from each other. A plurality of windows that are spaced apart from each other are defined in the pixel defining layer 13. Each window exposes one connection electrode 12. The conductive isolation structure 14 includes a conductive structure 141 arranged on the pixel defining layer 13 and a roof structure 142 arranged on the conductive structure 141. An orthographic projection of the conductive structure 141 on the driving substrate 112 at least partially overlaps with an orthographic projection of the connection electrode 12 on the driving substrate 112. A plurality of conductive vias are defined in the pixel defining layer 13 in an overlapping region. The conductive structure 141 is connected to the connection electrode 12 through the conductive via. The connection electrode 12 is electrically connected to a power routing line on the driving substrate 112 through a via. The conductive structure 141 is electrically coupled to a cathode of the display region 1, thereby realizing a signal connection between the cathode and the signal routing line.

In one embodiment, the encapsulation structure layer 15 is arranged on a side of the roof structure 142 away from the driving substrate 112. The encapsulation structure layer 15 includes a first inorganic encapsulation layer 151, an organic encapsulation layer 152, and a second inorganic encapsulation layer 153 sequentially stacked in a direction away from the driving structure layer 11.

The first inorganic encapsulation layer 151 extends in a direction away from the display region 1 to the border region 2 and covers an exposed surface of the dam structure 18. The organic encapsulation layer 152 extends in a direction away from the display region 1 to the border region 2. The first barrier structure 181 blocks the leveling of the organic encapsulation layer 152, reducing the risk of the organic encapsulation layer 152 leveling to an outside of the border region 2. The second inorganic encapsulation layer 153 extends in a direction away from the display region 1 to the border region 2 and covers an exposed organic encapsulation layer 152 and an exposed first inorganic encapsulation layer 151.

In one embodiment, the first barrier structure 181 is arranged on a surface of a side of the pixel defining layer 13 away from the driving substrate 112, that is, the first barrier structure 181 is arranged between the pixel defining layer 13 and the first inorganic encapsulation layer 151. A cross-sectional shape of the first barrier portion 181a in the first barrier structure 181 in a first direction includes, but is not limited to, a rectangular shape, a trapezoidal shape, an inverted trapezoidal shape, etc. A bottom surface of the first barrier portion 181a does not extend beyond a top surface of the pixel defining layer 13. The first direction refers to a direction perpendicular to the display panel 10. In one embodiment, an outer side surface of the first barrier portion 181a away from the display region 1 is a plane having a first inclination angle. The first inclination angle refers to an angle between the outer side surface of the first barrier portion 181a away from the display region 1 and a plane in the first direction. A range of the first inclination angle ranges from [0°90°). In one embodiment, the range of the first inclination angle ranges from 30 degrees and 60 degrees. The first inclination angle may also be, for example, 40 degrees, 45 degrees, 50 degrees, etc.

In one embodiment, an outer side surface of the second barrier portion 181b close to the display region 1 extends beyond a top surface of the first barrier portion 181a. That is, an orthographic projection of an edge of a bottom surface of the second barrier portion 181b close to the display region 1 on the driving structure layer 11 exceeds an orthographic projection of a top surface of the first barrier portion 181a on the driving structure layer 11. An outer side surface of the second barrier portion 181b away from the display region 1 does not extend beyond the top surface of the first barrier portion 181a. That is, an orthographic projection of an edge of bottom surface of the second barrier portion 181b away from the display region 1 on the driving structure layer 11 does not exceed an orthographic projection of the top surface of the first barrier portion 181a on the driving structure layer 11.

The outer side surface of the second barrier portion 181b away from the display region 1 is a plane having a second inclination angle. The second inclination angle refers to an angle between the outer side surface of the second barrier portion 181b away from the display region 1 and a plane in the first direction. A range of the second inclination angle ranges from [0°90°). In one embodiment, the range of the first inclination angle ranges from 30 degrees to 60 degrees. The first inclination angle may also be, for example, 40 degrees, 45 degrees, 50 degrees, etc. The first inclination angle may be equal to or different from the second inclination angle, and it may be specifically set according to actual conditions.

In a specific embodiment, a distance between an orthographic projection of an outer edge of the bottom surface of the second barrier portion 181b away from the display region 1 on a top surface of the first barrier portion 181a and an outer edge of the first barrier portion 181a away from the display region 1 is not zero. That is, the top surface of the first barrier portion 181a extends beyond the bottom surface of the second barrier portion 181b on a side away from the display region 1. An outer side surface of the second barrier portion 181b away from the display region 1, a portion of the top surface of the first barrier portion 181a, and an outer side surface of the first barrier portion 181a away from the display region 1 cooperatively form a stepped structure.

In a specific embodiment, as shown in FIG. 5 to FIG. 9, in order to reduce a formation of a step between the first barrier portion 181a and the second barrier portion 181b, simplify a connection structure between the first barrier portion 181a and the second barrier portion 181b, and reduce the probability of cracks occurring in the encapsulation structure layer 15 arranged at the connection between the first barrier portion 181a and the second barrier portion 181b, an edge of the bottom surface of the second barrier portion 181b away from the display region 1 is aligned with an edge of the top surface of the first barrier portion 181a away from the display region 1.

In some embodiments, a cross-sectional shape of the second barrier portion 181b in the first barrier structure 181 in the first direction may be a rectangular shape, a right-angled trapezoidal shape, an asymmetrical trapezoidal shape, an isosceles trapezoidal shape, etc.

In one embodiment, in order to reduce the probability of a void 17 forming at the outer side surface of the first barrier structure 181 close to the display region 1, a surface of the first inorganic encapsulation layer 151 away from the driving structure layer 11 does not exceed the bottom surface of the second barrier portion 181b. In a specific embodiment, a surface of the first inorganic encapsulation layer 151 away from the driving structure layer 11 is lower than the bottom surface of the second barrier portion 181b, so that the organic encapsulation layer 152 having a leveling characteristic fills a groove defined by the second barrier portion 181b in the first barrier structure 181, the first barrier portion 181a in the first barrier structure 181, and the driving structure layer 11, thereby reducing the probability of a void 17 forming in the groove and improving the encapsulation performance of the display panel 10.

In one embodiment, in order to facilitate the filling of the groove defined by the second barrier portion 181b in the first barrier structure 181, the first barrier portion 181a in the first barrier structure 181, and the driving structure layer 11, thereby reducing the probability of a void 17 forming in the groove, a surface of the second inorganic encapsulation layer 153 away from the driving structure layer 11 is not lower than the bottom surface of the second barrier portion 181b. To reduce an overflow of the organic encapsulation layer 152 having a leveling characteristic to a side of the first barrier structure 181 away from the display region 1, a surface of the organic encapsulation layer 152 away from the driving structure layer 11 is not higher than the top surface of the second barrier portion 181b.

In one embodiment, at least one of the first barrier portion 181a and the second barrier portion 181b is made of a metal material, and the material of the first barrier portion 181a is different from that of the second barrier portion 181b. For example, the materials of the first barrier portion 181a and the second barrier portion 181b may be different metals. In a specific embodiment, the material of the first barrier portion 181a may be copper, etc., and the material of the second barrier portion 181b may be aluminum, etc. In another embodiment, one of the first barrier portion 181a and the second barrier portion 181b is made of a metal material, and the other is made of an insulating material. The metal includes, but is not limited to, copper, aluminum, etc. The insulating material includes, but is not limited to, polyimide, etc.

In one embodiment, the first barrier structure 181 may be a single one or may be a plurality. When there are multiple first barrier structures 181, the first barrier structures 181 are arranged spaced apart from each other.

In one embodiment, the dam structure 18 further includes a second barrier structure 182 and/or a third barrier structure 183. The second barrier structure 182 and the third barrier structure 183 are respectively spaced apart from the first barrier structure 181. The second barrier structure 182 is arranged on a side of the first barrier structure 181 away from the display region 1, and the third barrier structure 183 is arranged on a side of the first barrier structure 181 close to the display region 1, as shown in FIG. 5 to FIG. 8. Since the second barrier structure 182 is spaced apart from the first barrier structure 181, a containment groove is formed between the first barrier structure 181 and the second barrier structure 182 in cooperation with the first inorganic encapsulation layer 151. The second barrier portion 181b may further block the overflow of the organic encapsulation layer 152 across the first barrier structure 181 through the containment groove, thereby preventing the organic encapsulation layer 152 from overflowing to the outside of the display panel 10. The third barrier structure 183 may slow down the flow speed of the organic encapsulation layer 152.

In one embodiment, the second barrier structure 182 includes a third barrier portion 182a and a fourth barrier portion 182b sequentially stacked in a direction from the driving structure layer 11 toward the encapsulation structure layer 15. At least a portion of the third barrier portion 182a away from the display region 1 does not extend beyond a top surface of the fourth barrier portion 182b.

In a specific embodiment, in order to facilitate the manufacturing of the second barrier structure 182, the structure, material, and shape of the third barrier portion 182a are the same as those of the first barrier portion 181a. The structure, material, and shape of the fourth barrier portion 182b are the same as those of the second barrier portion 181b, as shown in FIG. 5.

In a specific embodiment, in order to improve the encapsulation effect of the encapsulation structure layer 15, the second barrier structure 182 may include only the third barrier portion 182a, as shown in FIG. 7 and FIG. 9.

At least one of the structure, material, and shape of the second barrier structure 182 may also be different from that of the first barrier structure 181.

In a specific embodiment, since an amount of overflowed organic encapsulation material entering the containment groove is small, in order to reduce the probability of cracks occurring in the encapsulation structure layer 15 at a connection between a sidewall surface of the third barrier portion 182a and a sidewall surface of the fourth barrier portion 182b close to the display region 1, a portion of the fourth barrier portion 182b close to the display region 1 may be configured not to extend beyond a top surface of the third barrier portion 182a, as shown in FIG. 6. That is, an orthographic projection of an edge of a bottom surface of the fourth barrier portion 182b close to the display region 1 on the driving structure layer 11 does not exceed an orthographic projection of a top surface of the third barrier portion 182a on the driving structure layer 11. A portion of the fourth barrier portion 182b away from the display region 1 also does not extend beyond the top surface of the third barrier portion 182a. That is, an orthographic projection of an edge of the bottom surface of the fourth barrier portion 182b away from the display region 1 on the driving structure layer 11 does not exceed an orthographic projection of the top surface of the third barrier portion 182a on the driving structure layer 11.

In some embodiments, a cross-sectional shape of the third barrier portion 182a and/or the fourth barrier portion 182b in the second barrier structure 182 in the first direction may be a rectangular shape, a right-angled trapezoidal shape, an asymmetrical trapezoidal shape, an isosceles trapezoidal shape, etc. In this embodiment, in order to facilitate the manufacturing, cross-sectional shapes of both the third barrier portion 182a and the fourth barrier portion 182b in the first direction are isosceles trapezoidal shapes. An area of the top surface of the third barrier portion 182a is equal to an area of the bottom surface of the fourth barrier portion 182b. An edge of the third barrier portion 182a is aligned with an edge of the bottom surface of the fourth barrier portion 182b. The outer side surface of the third barrier portion 182a away from the display region 1 and the outer side surface of the fourth barrier portion 182b away from the display region 1 are located on the same plane. The outer side surface of the third barrier portion 182a close to the display region 1 and the outer side surface of the fourth barrier portion 182b close to the display region 1 are located on the same plane. In another embodiment, an inclination angle of the outer side surface of the third barrier portion 182a close to and/or away from the display region 1 may be smaller than the inclination angle of a corresponding outer side surface of the fourth barrier portion 182b. An inclination angle of the outer side surface of the third barrier portion 182a close to and/or away from the display region 1 may be greater than the inclination angle of a corresponding outer side surface of the fourth barrier portion 182b.

In one embodiment, the third barrier structure 183 includes a fifth barrier portion 183a and a sixth barrier portion 183b sequentially stacked in a direction from the driving structure layer 11 toward the encapsulation structure layer 15. At least a portion of the sixth barrier portion 183b close to the display region 1 extends beyond a top surface of the fifth barrier portion 183a, such that an eave structure is formed at a connection between the fifth barrier portion 183a and the sixth barrier portion 183b, so as to slow down a flow speed of the organic encapsulation layer 152.

In a specific embodiment, since the third barrier structure 183 is arranged on a side of the first barrier structure 181 close to the display region 1, the organic encapsulation layer 152 may overflow from the side of the third barrier structure 183 close to the display region 1 to a side away from the display region 1. Therefore, when a portion of the sixth barrier portion 183b away from the display region 1 extends beyond a top surface of the fifth barrier portion 183a, and the surface of the organic encapsulation layer 152 away from the driving structure layer 11 is not lower than the bottom surface of the sixth barrier portion 183b, the organic encapsulation layer 152 may fill a groove defined by a portion of the bottom surface of the sixth barrier portion 183b away from the display region 1, an outer side surface of the fifth barrier portion 183a away from the display region 1, and the driving structure layer 11, thereby avoiding a void to be formed at the groove defined by the portion of the bottom surface of the sixth barrier portion 183b away from the display region 1, the outer side surface of the fifth barrier portion 183a away from the display region 1, and the driving structure layer 11.

In a specific embodiment, in order to facilitate manufacturing, the shape, structure, and material of the third barrier structure 183 may also be the same as those of the first barrier structure 181.

The third barrier structure 183 may be one or more. When there are multiple third barrier structures 183, adjacent third barrier structures 183 are arranged spaced apart.

In one embodiment, the border region 2 further includes a fan-out region 20. The fan-out region 20 is connected to the display region 1 and includes multiple data fan-out lines. Each data fan-out line is configured to connect a data signal line of the display region 1 in a fan-out routing manner. The fan-out region 20 occupies a relatively large area, resulting in a larger width on a side of the border region 2 where the fan-out region 20 is arranged in the display panel 10. The border region 2 is a rectangular shape and includes an upper border, a lower border, a left border, and a right border. The lower border serves as the fan-out region 20.

In one embodiment, the dam structure 18 in the fan-out region 20 includes at least the first barrier structure 181 and the second barrier structure 182.

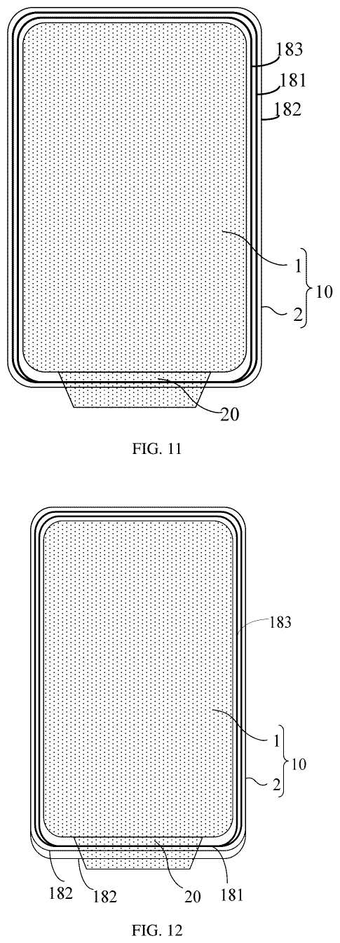

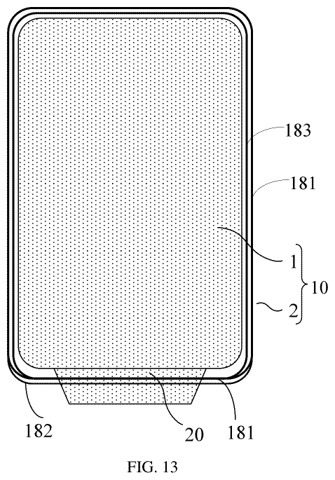

As shown in FIG. 11 to FIG. 13, FIG. 11 is a schematic planar structural view of a display panel provided in the first embodiment of the present disclosure, FIG. 12 is a schematic planar structural view of a display panel provided in the second embodiment of the present disclosure, FIG. 13 is a schematic planar structural view of a display panel provided in the third embodiment of the present disclosure.

In a specific embodiment, as shown in FIG. 11, since the fan-out region 20 includes multiple data fan-out lines, and the data fan-out lines transmit signals of the display region 1 to an outside of the border region 2, in order not to increase the difficulty of crossing lines for the data fan-out lines in the fan-out region 20 and at the same time improve the encapsulation reliability of the display panel 10, an upper border, an left border, and a right border in the border region 2 are each arranged with the first barrier structure 181, the second barrier structure 182, and the third barrier structure 183. Only the first barrier structure 181 and the second barrier structure 182 are arranged in the lower border of the border region 2.

In one embodiment, there are at least two second barrier structures 182, and adjacent second barrier structures 182 are spaced apart from each other.

In a specific embodiment, as shown in FIG. 12, in order to further increase the encapsulation capacity of the lower border without increasing the difficulty of crossing lines, the upper border, the left border, and the right border in the border region 2 are each arranged with the first barrier structure 181, the second barrier structure 182, and the third barrier structure 183. Only the first barrier structure 181 and the second barrier structure 182 are arranged in the lower border of the border region 2. The first barrier structure 181 is formed as two strips.

In one embodiment, the dam structure 18 in areas of the border region 2 other than the fan-out region 20 includes at least the first barrier structure 181 and the third barrier structure 183.

In a specific embodiment, as shown in FIG. 13, since only the lower border includes leads of the data fan-out lines, in order to increase the encapsulation capacity of the lower border, the upper border, the left border, and the right border in the border region 2 are each arranged with the first barrier structure 181 and the third barrier structure 183. The lower border in the border region 2 is arranged with the second barrier structure 182 and the third barrier structure 183.

In one embodiment, the present disclosure provides a manufacturing method of the display panel 10. The manufacturing method of the display panel 10 includes the following specific embodiments. The display panel 10 manufactured by the method is the display panel 10 as described in the above embodiments. In the following embodiments, in order to reduce the process steps, the first barrier structure 181, the second barrier structure 182, and the third barrier structure 183 are formed in the same layer, the materials of the first barrier portion 181a, the third barrier portion 182a, and the fifth barrier portion 183a are the same, the materials of the second barrier portion 181b, the fourth barrier portion 182b, and the sixth barrier portion 183b are the same.

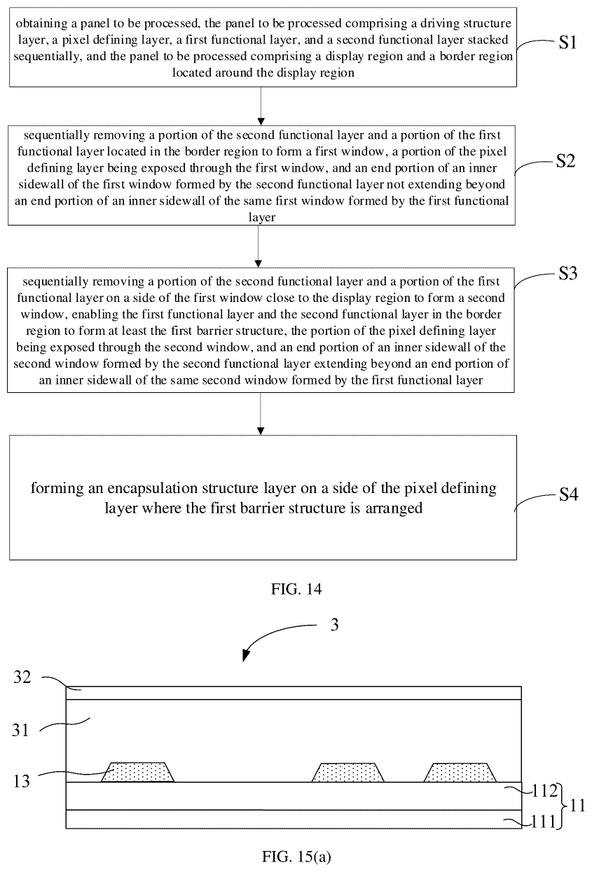

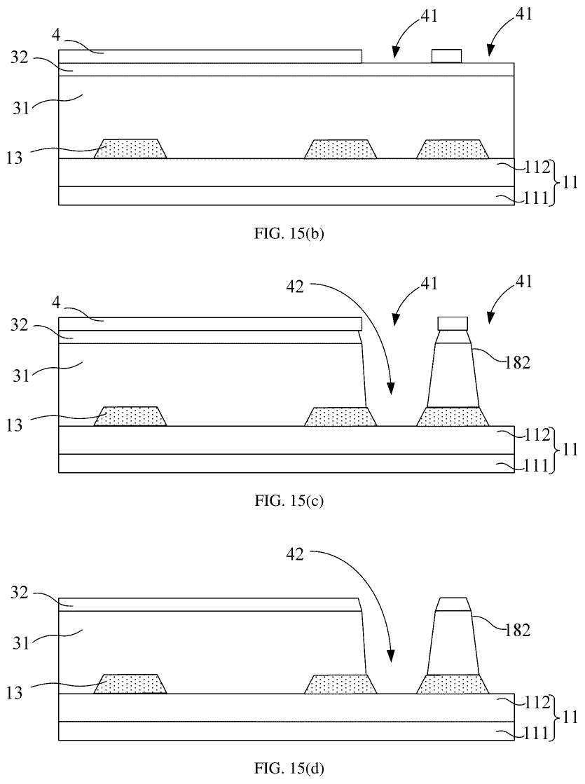

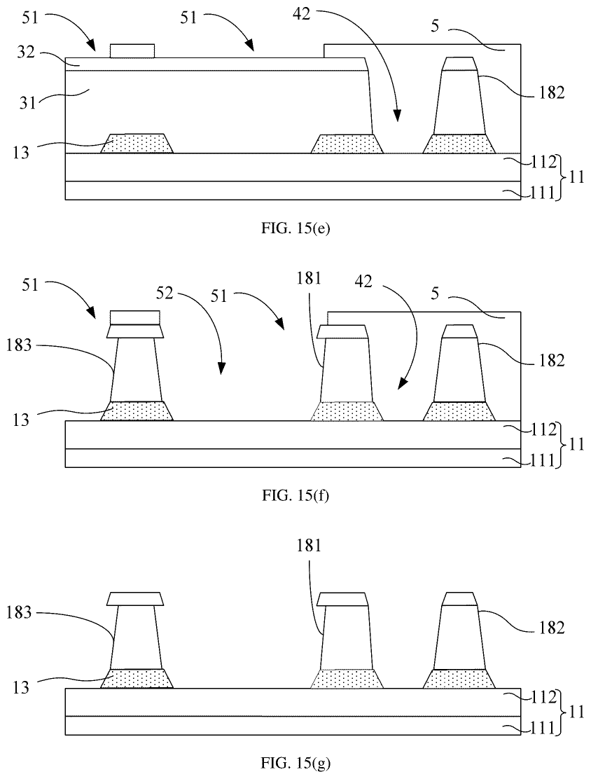

As shown in FIG. 14 and FIG. 15(a) to FIG. 15(e), FIG. 14 is a schematic flowchart of a method of manufacturing of a display panel provided in the present disclosure, and FIG. 15(a) to FIG. 15(e) are schematic cross-sectional views of a dam structure corresponding to each operation in the manufacturing method of the display panel shown in FIG. 14.

At block S1, a panel to be processed is obtained, the panel to be processed including a driving structure layer, a pixel defining layer, a first functional layer, and a second functional layer stacked sequentially, and the panel to be processed including a display region and a border region located around the display region.

In some embodiments, a driving substrate 112 covers a surface of a side of the substrate 111 to form a driving structure layer 11. A metal layer covers a side of the driving substrate 112 away from the substrate 111, and the metal layer is etched to obtain multiple connection electrodes 12 spaced apart from each other. A pixel defining layer 13 is formed on a side of the connection electrodes 12 away from the driving structure layer 11, and multiple windows are formed in the pixel defining layer 13. Each window exposes one connection electrode 12. A first functional layer 31 and a second functional layer 32 are sequentially stacked on the pixel defining layer 13 to form a panel to be processed 3, as shown in FIG. 15(a). The panel to be processed 3 includes a display region 1 and a border region 2 surrounding the display region 1.

A material of the first functional layer 31 and a material of the second functional layer 32 may be the same or different. The materials of the first functional layer 31 and the second functional layer 32 may be metal or insulating, and may be specifically set according to actual conditions.

In the following embodiment, an example of both the first functional layer 31 and the second functional layer 32 are metal, is described in detail. The materials of the first functional layer 31 and the second functional layer 32 are different. For example, the first functional layer 31 is copper, and the second functional layer 32 is aluminum.

At block S2, a portion of the second functional layer and a portion of the first functional layer located in the border region are sequentially removed to form a first window, a portion of the pixel defining layer being exposed through the first window, and an end portion of an inner sidewall of the first window formed by the second functional layer not extending beyond an end portion of an inner sidewall of the same first window formed by the first functional layer.

In some embodiments, a first photoresist layer 4 is formed on a surface of the second functional layer 32 away from the first functional layer 31, and the first photoresist layer 4 completely covers the second functional layer 32. At least one first opening 41 is formed in the first photoresist layer 4 in the border region 2 by exposure and development. A portion of the second functional layer 32 is exposed through the first opening 41, as shown in FIG. 15(b). A portion of the second functional layer 32 and a portion of the first functional layer 31 exposed through the first opening 41 are sequentially removed by wet etching to form a first window 42, as shown in FIG. 15(b). The first photoresist layer 4 is removed, as shown in FIG. 15(d).

Through the above operations, either an outer side surface of the second barrier structure 182 or an outer side surface of the first barrier structure 181 away from the display region 1 may be obtained.

At block S3, a portion of the second functional layer and a portion of the first functional layer are sequentially removed on a side of the first window close to the display region to form a second window, enabling the first functional layer and the second functional layer in the border region to form at least the first barrier structure, a portion of the pixel defining layer being exposed through the second window, and an end portion of an inner sidewall of the second window formed by the second functional layer extending beyond an end portion of an inner sidewall of the same second window formed by the first functional layer.

In some embodiments, a second photoresist layer 5 is formed on a side of the second functional layer 32 away from the first functional layer 31. The second photoresist layer 5 fills the first window 42 and covers the second functional layer 32. At least one second opening 51 is formed in the second photoresist layer 5 in a region on a side of the first window 42 close to the display region 1 by exposure and development, as shown in FIG. 15(e). A portion of the second functional layer 32 is exposed through the second opening 51. A portion of the second functional layer 32 and a portion of the first functional layer 31 exposed through the second opening 51 are sequentially removed by exposure and development to form a second window 52, as shown in FIG. 15(f). The second photoresist layer 5 is removed, as shown in FIG. 15(g).

Through the above blocks, any one of the third barrier structure 183, the outer side surface of the first barrier structure 181 close to the display region 1, and the conductive isolation structure 14 in the display region 1 may be formed in the border region 2.

At block S4, an encapsulation structure layer is formed on a side of the pixel defining layer where the first barrier structure is arranged.

In some embodiments, a first inorganic encapsulation layer 151 is formed by chemical vapor deposition on a surface of a side of the pixel defining layer 13 where the first barrier structure 181, the second barrier structure 182, and the third barrier structure 183 are arranged. An organic encapsulation material is arranged onto a surface of the first inorganic encapsulation layer 151 in the display region 1 by inkjet printing. The organic encapsulation material has fluidity and flows from the display region 1 to the border region 2. The organic encapsulation material first flows to the third barrier structure 183, and the flow speed is reduced by the third barrier structure 183. Subsequently, the organic encapsulation material flows to the first barrier structure 181. When the organic encapsulation material overflows to a side of the first barrier structure 181 away from the display region 1, the second barrier structure 182 blocks the organic encapsulation material again. Then, the organic encapsulation material forms an organic encapsulation layer 152 on a surface of a side of the first inorganic encapsulation layer 151 away from the pixel defining layer 13. A second inorganic encapsulation layer 153 is formed again on a surface of a side of the organic encapsulation layer 152 away from the pixel defining layer 13 by chemical vapor deposition. Through the above blocks, the encapsulation structure layer 15 may be obtained, as shown in FIG. 4.

In one embodiment, a metal layer is formed on a side of the encapsulation structure layer 15 away from the driving structure layer 11 by a method such as spraying, and the metal layer is patterned to obtain a wiring layer, as shown in FIG. 3.

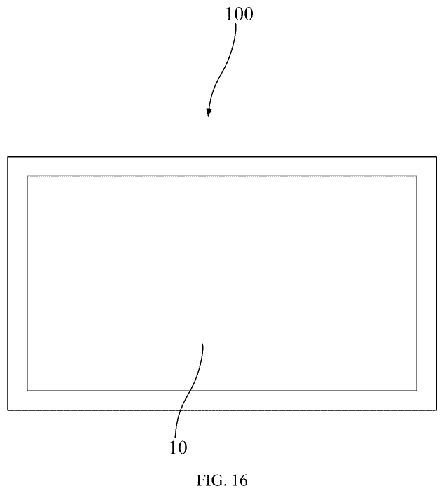

As shown in FIG. 16, FIG. 16 is a schematic structural view of a display apparatus 100 provided in an embodiment of the present disclosure.

In the present embodiment, a display apparatus 100 is provided. The display apparatus 100 may be configured in fields such as tablets, mobile phones, vehicle-mounted systems, lighting, etc.

The display apparatus 100 includes a display panel 10. The specific structure and function of the display panel 10 are the same as or similar to those of the display panel 10 in the above embodiments, and the same technical effects may be achieved. For detailed descriptions, reference may be made to the above, which will not be repeated herein.

The display panel 10 in the display apparatus 100 adopts the display panel 10 described in the above embodiments. In the dam structure 18, the first barrier structure 181 is configured such that a portion of the second barrier portion 181b away from the display region 1 does not extend beyond a top surface of the first barrier portion 181a, so that a sidewall surface of the first barrier structure 181 away from the display region 1 does not form an eave structure, thereby avoiding defects such as cracks and voids 17 in the first barrier structure 181 caused by the eave structure. By configuring a portion of the second barrier portion 181b close to the display region 1 to extend beyond a top surface of the first barrier portion 181a, the sidewall surface of the first barrier structure 181 close to the display region 1 forms an eave structure, so as to facilitate edge sealing of the encapsulation structure layer 15 and improve the encapsulation effect of the display panel 10.

The above are merely embodiments of the present disclosure and are not intended to limit the scope of patent protection of the present disclosure. Any equivalent structural or procedural transformations made based on the content of the specification and drawings of the present disclosure, or any direct or indirect application in other related technical fields, shall likewise fall within the scope of protection of the present disclosure.

1. A display panel, having a display region and a border region located around the display region, wherein the display panel comprises:
a driving structure layer, a pixel defining layer, and an encapsulation structure layer sequentially stacked;
a dam structure, arranged in the border region and arranged between the pixel defining layer and the encapsulation structure layer;
wherein the dam structure comprises a first barrier structure, the first barrier structure comprises a first barrier portion and a second barrier portion sequentially stacked in a direction from the pixel defining layer to the encapsulation structure layer, a portion of the second barrier portion close to the display region extends beyond a top surface of the first barrier portion, and a portion of the second barrier portion away from the display region does not extend beyond the top surface of the first barrier portion.

2. The display panel according to claim 1, wherein the encapsulation structure layer comprises a first inorganic encapsulation layer, an organic encapsulation layer, and a second inorganic encapsulation layer sequentially stacked in a direction away from the pixel defining layer, and a surface of the first inorganic encapsulation layer away from the pixel defining layer does not extend beyond a bottom surface of the second barrier portion.

3. The display panel according to claim 2, wherein a surface of the organic encapsulation layer away from the pixel defining layer is not lower than the bottom surface of the second barrier portion and not higher than a top surface of the second barrier portion.

4. The display panel according to claim 1, wherein at least one of the first barrier portion and the second barrier portion is made of a metal material, and a material of the first barrier portion is different from a material of the second barrier portion.

5. The display panel according to claim 1, wherein the dam structure further comprises a second barrier structure and/or a third barrier structure, the second barrier structure is arranged on a side of the first barrier structure away from the display region, and the third barrier structure is arranged on a side of the first barrier structure close to the display region, the second barrier structure comprises a third barrier portion and a fourth barrier portion sequentially stacked in a direction from the pixel defining layer to the encapsulation structure layer, the fourth barrier portion completely covers a top surface of the third barrier portion, two sides of the fourth barrier portion extend beyond the top surface of the third barrier portion, the third barrier portion comprises a fifth barrier portion and a sixth barrier portion sequentially stacked in a direction from the pixel defining layer to the encapsulation structure layer, the sixth barrier portion at least partially covers a top surface of the fifth barrier portion, and an orthographic projection of the sixth barrier portion onto the top surface of the fifth barrier portion does not extend beyond the top surface of the fifth barrier portion.

6. The display panel according to claim 4, wherein the border region comprises a fan-out region, the dam structure in the fan-out region comprises at least the first barrier structure and the second barrier structure spaced apart from each other, at least two second barrier structures are in the fan-out region, and adjacent second barrier structures are arranged spaced apart.

7. The display panel according to claim 6, wherein the dam structure in the border region other than the fan-out region comprises at least the first barrier structure and the third barrier structure.

8. The display panel according to claim 1, wherein the display panel further comprises a plurality of connection electrodes and a conductive isolation structure, the driving structure layer comprises a substrate and a driving substrate sequentially stacked, each connection electrode is arranged between the pixel defining layer and the driving substrate, and the plurality of connection electrodes are spaced apart from each other.

9. The display panel according to claim 8, wherein the conductive isolation structure comprises a conductive structure arranged on the pixel defining layer and a roof structure arranged on the conductive structure, and an orthographic projection of the conductive structure on the driving substrate at least partially overlaps with an orthographic projection of the connection electrode on the driving substrate.

10. A method of manufacturing a display panel, comprising:
obtaining a panel to be processed, the panel to be processed comprising a driving structure layer, a pixel defining layer, a first functional layer, and a second functional layer stacked sequentially, and the panel to be processed comprising a display region and a border region located around the display region;
sequentially removing a portion of the second functional layer and a portion of the first functional layer located in the border region to form a first window, a portion of the pixel defining layer being exposed through the first window, and an end portion of an inner sidewall of the first window formed by the second functional layer not extending beyond an end portion of an inner sidewall of the same first window formed by the first functional layer;
sequentially removing a portion of the second functional layer and a portion of the first functional layer on a side of the first window close to the display region to form a second window, enabling the first functional layer and the second functional layer in the border region to form at least the first barrier structure, the portion of the pixel defining layer being exposed through the second window, and an end portion of an inner sidewall of the second window formed by the second functional layer extending beyond an end portion of an inner sidewall of the same second window formed by the first functional layer;
forming an encapsulation structure layer on a side of the pixel defining layer where the first barrier structure is arranged.

11. The method according to claim 10, wherein the sequentially removing a portion of the second functional layer and a portion of the first functional layer located in the border region to form a first window, comprises:
forming a first photoresist layer on a surface of the second functional layer away from the first functional layer, the first photoresist layer completely covering the second functional layer;
defining at least one first opening in the first photoresist layer in the border region, a portion of the second functional layer being exposed through the at least one first opening;
sequentially removing a portion of the second functional layer and a portion of the first functional layer being exposed through the at least one first opening to form a first window;
removing the first photoresist layer;
wherein the sequentially removing a portion of the second functional layer and a portion of the first functional layer on a side of the first window close to the display region to form a second window, comprises:
forming a second photoresist layer on the side of the second functional layer away from the first functional layer, the second photoresist layer filling the first window and covering the second functional layer;
defining at least one second opening on the second photoresist layer in a region on a side of the first window close to the display region, a portion of the second functional layer being exposed through the at least one second opening;
sequentially removing a portion of the second functional layer and a portion of the first functional layer being exposed through the at least one second opening to form a second window;
removing the second photoresist layer.

12. A display apparatus, comprising a display panel and a power supply, the display panel having a display region and a border region located around the display region, wherein the display panel comprises:
a driving structure layer, a pixel defining layer, and an encapsulation structure layer sequentially stacked;
a dam structure, arranged in the border region and arranged between the pixel defining layer and the encapsulation structure layer;
wherein the dam structure comprises a first barrier structure, the first barrier structure comprises a first barrier portion and a second barrier portion sequentially stacked in a direction from the pixel defining layer to the encapsulation structure layer, a portion of the second barrier portion close to the display region extends beyond a top surface of the first barrier portion, and a portion of the second barrier portion away from the display region does not extend beyond the top surface of the first barrier portion.

13. The display apparatus according to claim 12, wherein the encapsulation structure layer comprises a first inorganic encapsulation layer, an organic encapsulation layer, and a second inorganic encapsulation layer sequentially stacked in a direction away from the pixel defining layer, and a surface of the first inorganic encapsulation layer away from the pixel defining layer does not extend beyond a bottom surface of the second barrier portion.

14. The display apparatus according to claim 13, wherein a surface of the organic encapsulation layer away from the pixel defining layer is not lower than the bottom surface of the second barrier portion and not higher than a top surface of the second barrier portion.

15. The display apparatus according to claim 12, wherein at least one of the first barrier portion and the second barrier portion is made of a metal material, and a material of the first barrier portion is different from a material of the second barrier portion.

16. The display apparatus according to claim 12, wherein the dam structure further comprises a second barrier structure and/or a third barrier structure, the second barrier structure is arranged on a side of the first barrier structure away from the display region, and the third barrier structure is arranged on a side of the first barrier structure close to the display region, the second barrier structure comprises a third barrier portion and a fourth barrier portion sequentially stacked in a direction from the pixel defining layer to the encapsulation structure layer, the fourth barrier portion completely covers a top surface of the third barrier portion, two sides of the fourth barrier portion extend beyond the top surface of the third barrier portion, the third barrier portion comprises a fifth barrier portion and a sixth barrier portion sequentially stacked in a direction from the pixel defining layer to the encapsulation structure layer, the sixth barrier portion at least partially covers a top surface of the fifth barrier portion, and an orthographic projection of the sixth barrier portion onto the top surface of the fifth barrier portion does not extend beyond the top surface of the fifth barrier portion.

17. The display apparatus according to claim 15, wherein the border region comprises a fan-out region, the dam structure in the fan-out region comprises at least the first barrier structure and the second barrier structure spaced apart from each other, at least two second barrier structures are in the fan-out region, and adjacent second barrier structures are arranged spaced apart.

18. The display apparatus according to claim 17, wherein the dam structure in the border region other than the fan-out region comprises at least the first barrier structure and the third barrier structure.

19. The display apparatus according to claim 12, wherein the display panel further comprises a plurality of connection electrodes and a conductive isolation structure, the driving structure layer comprises a substrate and a driving substrate sequentially stacked, each connection electrode is arranged between the pixel defining layer and the driving substrate, and the plurality of connection electrodes are spaced apart from each other.

20. The display apparatus according to claim 19, wherein the conductive isolation structure comprises a conductive structure arranged on the pixel defining layer and a roof structure arranged on the conductive structure, and an orthographic projection of the conductive structure on the driving substrate at least partially overlaps with an orthographic projection of the connection electrode on the driving substrate.
